(19) United States
(12) Patent Application Publication
(10) Pub. No.: US 2004/0048089 A1
(43) Pub. Date: Mar. 11, 2004

(54) Inner magnetic shielding material and method for production thereof

(76) Inventors: Yoshikazu Yamanaka, Sakai-shi (JP); Shouichi Tsunematsu, Hannan-shi (JP); Sachio Matsuo, Takatsuki-shi (JP); Hisao Sakamoto, Gojo-shi (JP); Kenichiro Kobayashi, Kishiwada-shi (JP)

Correspondence Address: Russell D Orkin, 700 Koppers Building, 436 Seventh Avenue, Pittsburgh, PA, 15219-1818, US

(21) Appl. No.: 10/451,961

(22) PCT Filed: Dec. 28, 2000
(86) PCT No.: PCT/JP00/09376

(51) Int. Cl. H01F 1/00

(52) U.S. Cl. 428/611; 427/127

(57) ABSTRACT

A material for an inner magnetic shield which has rust preventing properties, good degreasing and washing properties, no danger of generating corrosive gases, and good press workability is provided. This material has coating film of an organic resin consisting essentially of C and H, or of C, H, and O, or of C, H, O, and N with a thickness of 0.3-5 μm on at least one side of a cold rolled steel sheet having a surface roughness of 0.2-3 μm Ra. This material can be manufactured by a step of annealing a cold rolled steel sheet, a step of adjusting the surface roughness of the annealed cold rolled steel sheet to 0.2-3 μm Ra, and a step of forming an organic resin coating film consisting essentially of C and H, or of C, H, and O, or of C, H, O, and N and having a thickness of 0.3-5 μm on at least one side of the cold rolled steel sheet.

### TECHNICAL FIELD

This invention relates to a material for an inner magnetic shield, which is a part installed within a cathode ray tube for use in a color television, and a method for its manufacture.

### BACKGROUND ART

The basic structure of a cathode ray tube (CRT) for a color television comprises an electron gun and a fluorescent screen which converts electron beams into images. These are housed inside a glass tube formed by joining a panel member and a funnel member.

A magnetic shield member (referred to below simply as a magnetic shield) is disposed on the side of the cathode ray tube in order to prevent deflection of electron beams due to the earth's magnetism. This magnetic shield includes an inner magnetic shield which is installed inside the cathode ray tube and an outer magnetic shield which is installed on the outside of the cathode ray tube.

Materials used for these inner and outer magnetic shields are required to have press workability and the ability to dissipate heat in addition to magnetic properties such as a high permeability and a low coercive force. Normally, cold rolled steel sheet, and particularly aluminum killed steel, silicon killed steel, aluminum trace steel, silicon trace steel, and the like are used as this material. Aluminum or silicon trace steel is a steel in which the content of Al or Si is below detectable limits.

A conventional material for an inner magnetic shield passes through the following steps in the manufacture of an inner magnetic shield and its incorporation into a cathode ray tube:

press working of material→washing→blackening treatment→

sealing of the cathode ray tube→degasification of the cathode ray tube.

Among these steps, the blackening treatment is performed mainly for the purpose of primary or temporary rust prevention to protect the inner magnetic shield manufactured by press working from rusting until it is incorporated into a cathode ray tube. In addition to a primary rust preventing effect, the blackened film which is formed has the effects of increasing heat dissipation by the inner magnetic shield and of preventing irregular reflections of electron beams.

In this blackening treatment, an iron oxide film mainly comprising magnetite (Fe₃O₄) is formed on the steel surface by heat treatment in a weakly oxidizing high temperature atmosphere (approximately 550-590° C.). Although the resulting iron oxide film is porous, it has a dense structure and hence a considerable corrosion resistance, so it is effective for providing the above-described primary rust prevention.

However, since blackening treatment is performed on processed parts after press working rather than on steel sheet materials, it is normally carried out by the manufacturers of cathode ray tubes (namely, by the users of magnetic shield materials). If blackening treatment is carried out during the manufacturing stage of an inner magnetic shield material, the adhesion of the resulting Fe₃O₄-based blackened film is poor, so it peels off during press working carried out by the user, and the desired corrosion resistance cannot be obtained. Therefore, it is customary for the users of the material to install heat treatment equipment which is used only for blackening treatment and perform blackening treatment themselves. Therefore, the costs of blackening treatment become high.

In order to make costly blackening treatment unnecessary, it has been attempted to impart corrosion resistance to the inner magnetic shield material itself For example, JP 2-228466 A1 (1990) discloses an inner magnetic shield material having a FeO-based blackened film, which is previously formed on the surface of a steel sheet by heat treatment using an oxidizing gas and a non-oxidizing gas in a continuous annealing line for cold rolled steel sheet. Heat treatment for forming this blackened film is carried out by the following three different heat treatment stages which are performed sequentially:

(1) heating-up stage: forming an Fe₃O₄ film in an oxidizing gas;

(2) soaking stage: transforming Fe₃O₄ into FeO in a non-oxidizing gas; and

(3) cooling stage: forming a FeO-based blackened film by rapid cooling in a non-oxidizing gas.

However, this method has the following problems.

First, in order to form a blackened film having good adhesion which can withstand working, it is necessary to strictly control the heating pattern and the atmosphere of heat treatment so as to form a thin FeO-based blackened film. However, fluctuations in these parameters are unavoidable, and there are cases in which the blackened film becomes too thick and its adhesion becomes poor.

Secondly, due to the fact that films of iron oxides including FeO are extremely hard, during press working of a material, various problems occur such as peeling of the blackened film in the portion being worked, damage to dies used for punching or similar working, and shortening of the service life of dies due to wear.

Thirdly, if the film thickness is decreased in order to guarantee its adhesion, its corrosion resistance becomes inadequate, and rusting may take place during storage of an inner magnetic shield material or during the period until the cathode ray tube having an inner magnetic shield therein is sealed.

JP 6-36702 A1 (1994) discloses an inner magnetic shield material which is i5 formed by applying thin Ni plating to cold rolled steel sheet, and then performing annealing to form a Ni—Fe diffusion layer at the interface between the plating and the steel sheet.

However, in order to perform Ni plating, electroplating equipment and electrical energy are required, and a large amount of waste plating liquid is formed, which has a significant adverse effect on the environment.

With a Ni-plated steel sheet, it is well known that the adhesion and corrosion resistance of the plating are increased if a Ni—Fe diffusion layer is formed by annealing after Ni plating. However, it is also known that the thickness of the resulting diffusion layer is difficult to control and corrosion resistance is decreased if diffusion caused by annealing is excessive. In particular, the plated film formed by the above-described Ni plating is thin, and it is thus difficult to prevent excessive diffusion with certainty.

Thus, the above-described two types of inner magnetic shield material which do not require blackening treatment are each manufactured under strictly controlled conditions including annealing, but considering unavoidable fluctuations in annealing conditions, it is difficult to manufacture a product with consistent quality.

In addition, in both of these methods, the formation of hematite (rust) may occur during the sealing step which is carried out in air at a high temperature, and in such cases, it may not be possible to perform degasification to the necessary vacuum in the subsequent degasification step for the cathode ray tube.

Furthermore, with the prior-art inner magnetic shields, including conventional inner magnetic shields which have been subjected to blackening treatment after press working, the film formed on the surface is porous, and during washing which is performed prior to sealing of a cathode ray tube, oily dirt adhering after blackening treatment or oils such as rust preventing oil or working oil which are applied to the material may not be completely removed. As a result, as will be described in detail further on, the oil decomposes and generates harmful gas when the inner magnetic shield is exposed to a high temperature during sealing of the cathode ray tube, and the gas may damage parts other than the inner magnetic shield installed inside the cathode ray tube.

### DISCLOSURE OF THE INVENTION

Thus, there is still a demand for an inner magnetic shield material which is previously imparted with corrosion resistance in order to make it possible to omit blackening treatment by the user, which can be manufactured without treatment such as annealing requiring strict control, which can be subjected to press working without problems, which exhibits adequate corrosion resistance comparable to that provided by blackening treatment even after press working, which can protect the material from rusting during storage of an inner shield material and up to the sealing step of a cathode ray tube, and which can prevent the formation of hematite (rust) even if exposed to air at a high temperature during the sealing step.

An object of this invention is to provide such an inner magnetic shield material and a method for its manufacture.

Another object of this invention is to provide an inner magnetic shield material which can be well degreased by washing to prevent the formation of harmful gases during sealing of a cathode ray tube, and to a method for its manufacture.

According to one aspect, the present invention is an inner magnetic shield material for use in manufacturing an inner magnetic shield to be installed inside a cathode ray tube for a color television, characterized in that it comprises a cold rolled steel sheet having a coating film of an organic resin consisting essentially of C and H, or of C, H, and O, or of C, H, O, and N with a thickness of 0.3-5 μm on at least one surface of the steel sheet having a surface roughness of 0.2-3 μm Ra.

According to another aspect, the present invention is an inner magnetic shield part to be installed inside a cathode ray tube for a color television, characterized by being manufactured by press working of a material which comprises a cold rolled steel sheet having a coating film of an organic resin consisting essentially of C and H, or of C, H, and O, or of C, H, O, and N with a thickness of 0.3-5 μm on at least one surface of the steel sheet having a surface roughness of 0.2-3 μm Ra.

The present invention also provides a method of manufacturing a material for an inner magnetic shield to be installed inside a cathode ray tube for a color television, characterized by forming a coating film of an organic resin consisting essentially of C and H, or of C, H, and O, or of C, H, O, and N and having a thickness of 0.3-5 μm on at least one surface of an annealed cold rolled steel sheet adjusted to have a surface roughness of 0.2-3 μm Ra by application of a resin coating composition followed by baking.

The thickness of the organic resin coating film means a value calculated from the coating weight (g/m²) and density (g/cm³) of the film. The coating weight is calculated as the difference in weight between before and after removal when just the coating film is removed by chemical treatment from a material on which the coating film was applied.

An inner magnetic shield material according to the present invention can be used to manufacture an inner magnetic shield without blackening treatment after press working. Furthermore, during a step of sealing a cathode ray tube after the manufactured inner magnetic shield is incorporated into the cathode ray tube, the organic resin coating film on the material undergoes decomposition by combustion and thus forms a film on the surface of the material similar to a blackened film, and it can exhibit the effects of dissipating heat and preventing irregular reflections of electron beams in the same way as a conventional inner magnetic shield having a blackened film formed after press working.

In a series of steps (excluding blackening treatment) from the manufacture of an inner magnetic shield through its incorporation into a cathode ray tube, as will next be described, an inner magnetic shield material according to the present invention (referred to below as the inventive material) has advantageous properties compared to a conventional inner magnetic shield material which does not require blackening treatment and which has Ni plating or a FeO-based blackened film (referred to below as a conventional material) or a cold rolled steel sheet which has been subjected to blackening treatment.

Press Working

Press working of the material is a step of fabricating an inner magnetic shield having a prescribed shape by punching of a blank followed by bending or drawing. Compared to a cold rolled steel sheet (referred to below as a cold rolled material), a conventional material usually has an extremely hard surface layer, and thus it has drawbacks including that forming causes severe wear of the die which is used, particularly during punching of a blank, thereby decreasing the service life of the die, impairing the efficiency of working, and increasing working costs. In particular, the workability of a conventional material having a blackened film primarily comprising FeO is extremely poor.

Washing

Washing is carried out after press working in order to remove rust preventing oil, which is applied during the step of manufacturing the material in order to prevent the material from rusting, and various dirt. A conventional material is more difficult to degrease than a cold rolled material, and rust preventing oil often remains even after degreasing. This is because the surface of the film formed on a conventional material is porous, and rust preventing oil which enters into the minute pores cannot be completely degreased under the same degreasing conditions as for a cold rolled material. The inventive material has its surface covered with a resin coating film so as to fill surface irregularities present in a cold rolled material and flatten the surface, so the surface becomes smooth, and it exhibits degreasing properties which is at least as good as that of a cold rolled material.

Blackening Treatment

With a cold rolled material, blackening treatment is carried out by heat treatment after press working. As described above, this step has the drawback that it is expensive. The inventive material has corrosion resistance comparable to a blackened film even after rust preventing oil is removed by washing after press working. Therefore, even if blackening treatment is omitted, there is no occurrence of rust up to its incorporation into a cathode ray tube. With a conventional material, this corrosion resistance is also inadequate.

Sealing of a Cathode Ray Tube

In the step of sealing a cathode ray tube after the inner magnetic shield and other parts are incorporated into the interior of a cathode ray tube, the divided glass tube (the panel member and the funnel member) are heated to a high temperature and sealed. The sealing step is carried out by heating the above members in air (or in an atmosphere having a similar composition) to a high temperature in the vicinity of 450° C. near the melting point of glass and holding this temperature for around 15 minutes.

With an inner magnetic shield made from the inventive material, the organic resin coating film undergoes combustion and decomposition during the heating of the sealing step. The organic resin coating film of the inventive material does not include elements such as S, Cl, F, or the like which could generate corrosives gases. Therefore, the gases which are generated by the combustion and decomposition of the resin coating film during heating does not damage the performance of parts other than the inner magnetic shield.

With a conventional material, the film is inorganic and does not combust during the sealing step. However, as stated earlier, a conventional material may not be able to be completely degreased during the washing step, and rust preventing oil, if remains after washing, combusts during the heating in this step to generate corrosive gases containing S, Cl, F, or the like, and may damage the performance of parts other than the inner magnetic shield.

With any of the above-described conventional materials, while it is heated in air during the sealing step, the surface of the material is exposed to a high temperature atmosphere having a high oxygen concentration, and Fe₂O₃ (hematite) may readily form on the surface, leading to the occurrence of red-colored rust. As will be described with respect to the next step, this rust makes the quality of the cathode ray tube unstable.

With the inventive material, the CO, CO₂, and H₂O gases which are formed by the combustion and decomposition of the coating film maintain the oxygen concentration near the surface of the steel sheet in a suitable state in which a blackened film can easily form, and a film resembling a blackened film is formed on the surface of the steel sheet in a stable manner. Due to this film, the effects of increasing heat dissipation ability and of preventing irregular reflections of electron beams can be exhibited.

Degasification of the Cathode Ray Tube

Degasification of the cathode ray tube is a step in which the interior of the cathode ray tube is evacuated. In this step, the interior of the cathode ray tube is degasified to a vacuum of approximately 10⁻⁵ Torr while maintaining the temperature at around 350° C. This degree of vacuum is indispensable in order for electron beams not to be scattered by gas in the atmosphere, and it directly affects the performance of the cathode ray tube.

With a conventional material, as described earlier, rust could form during the sealing step. If rust is formed, it has the property of adsorbing gas in the atmosphere, and the adsorbed gas can not be easily removed in the degasification step. Therefore, the necessary vacuum may not be obtained in the degasification step, or after a cathode ray tube product is manufactured, the adsorbed gas may be gradually released in the interior of the cathode ray tube and scatter electron beams, thereby making the quality of the cathode ray tube unstable.

With the inventive material, as described above, a film which is similar to a blackened film is formed in the sealing step in a stable manner, and thus properties which are in no way inferior to those of a normally used inner magnetic shield in which a cold rolled material has undergone blackening treatment are obtained.

### BEST MODE FOR CARRYING OUT THE INVENTION

An inner magnetic shield material according to the present invention has an organic resin coating film consisting essentially of the elements C and H, or of the elements C, H, and O, or of the elements C, H, O, and N with a thickness of 0.3-5 μm on at least one surface of a cold rolled steel sheet having a surface roughness of 0.2-3 μRa.

Preferably, the cold rolled steel sheet is one having excellent magnetic properties. Some examples of such steel sheet are aluminum killed steel sheet, silicon killed steel sheet, aluminum trace steel sheet, and silicon trace steel sheet which have conventionally been used for inner magnetic shields.

If the surface roughness of the cold rolled steel sheet exceeds 3 μm Ra, the thickness of the resin coating film necessary to fill in surface irregularities of this size becomes large. If the thickness of the resin coating film is insufficient and the surface irregularities cannot be completely filled in, corrosion resistance becomes poor, and after working, rust may develop in the period until sealing of the cathode ray tube. On the other hand, if the thickness of the resin coating film is too great in an attempt to completely cover the large surface irregularities, not only does the amount of gas which is generated in the step of sealing the cathode ray tube increase, but the film cannot be decomposed by combustion adequately, and part of the film may remain in the degasification and subsequent steps (defective combustion of the film). The remaining film undergoes decomposition by combustion at the time of heat treatment in the degasification step, and thus the efficiency of degasification is impaired. The sealing step is carried out by heating at a temperature of approximately 450° C. for around 15 minutes, so there is a limit to the thickness of the resin coating film which can undergo combustion and decomposition during this heating, and it is necessary for it to be at most 5 μm. With a material having a surface roughness exceeding 3 μm Ra, it is difficult to control the thickness of the film so as to satisfy both corrosion resistance and degasification efficiency.

If the surface roughness of the cold rolled steel sheet is less than 0.2 μm Ra, the thickness of the resin coating film necessary to fill in the surface irregularities is small, and problems do not occur in the subsequent sealing and degasification steps. However, there is a tendency for problems to develop such as slipping of the material during press working or for materials to be too tightly adhered to each other and to be difficult to-separate from each other. During the press working step, the material in the form of a coil is unwound and fed for punching by a certain length suitable therefor through a pair of measuring rolls. If the material slides too much at this time, slippage takes place between the rolls and the material, and it becomes difficult to feed an accurate length of the material. Punched blanks are stacked atop each other and sent to the next press working station. If the materials adhere too tightly to each other at this time, a plurality of sheets of the material may be sent to the next press working station while adhered to each other and undergo press working, which may result in damage to the die or inability to perform working to a prescribed shape.

For these reasons, a suitable surface roughness of the cold rolled steel sheet is 0.2-3 μm Ra. The surface roughness is more preferably 0.4-2 μm Ra and most preferably in the range of 0.5-1.5 μm Ra.

If the thickness of the organic resin coating film exceeds 5 μm, as previously mentioned, part of the film may remain due to incomplete decomposition by combustion in the sealing step, and this causes the generation of gas in the subsequent degasification step, which impedes degasification procedure. On the other hand, if the thickness of the resin coating film is less than 0.2 μm, the corrosion resistance of the material greatly decreases. Accordingly, a thickness of 0.2-5 μm for the organic resin coating film is suitable, preferably it is 1-4 μm, and more preferably it is in the range of 2-3.5 μm.

There is a minimum necessary thickness of the organic resin coating film depending on the surface roughness of the material in order to ensure corrosion resistance. Therefore, the film thickness is selected depending on the surface roughness to guarantee corrosion resistance. As a guideline, the thickness of the resin coating film is made at least ½ of Ra and preferably larger than Ra. Increasing the thickness of the resin coating film more than needs is not desirable from the standpoint of manufacturing costs.

The organic resin coating film consists essentially of the elements C and H, or C, H, and O, or C, H, O, and H, so it does not generate a corrosive gas when it undergoes combustion and decomposition. The organic resin coating film is preferably one having a film strength such that it will not peel off during press working, and it preferably easily combusts and decomposes when heated in air at 450° C. so as to be removed during the sealing step.

The resin used as the resin coating film in the present invention can be selected from resins for bake coating used in the manufacture of precoated steel sheet which satisfy the above-described requirements. Some examples of suitable resins are urethane resins, acrylic resins, polyester resins, polyolefin resins, polystyrene resins, polyamide resins, and the like.

In order to increase corrosion resistance, the organic resin coating film may contain a metal oxide, such as SiO₂, Al₂O₃, or TiO₂. This metal oxide is preferably added to the resin coating composition in the form of a sol or submicron fine particles. The content of the metal oxide in the resin coating film is preferably at most 80 mass %. If metal oxides are present in a larger amount, coating procedure is impaired, for example, due to an excessive increase in the viscosity of the resin coating composition. A more preferred content of the metal oxide is 5-50 mass %.

Metal oxides in the resin coating film do not undergo combustion and decomposition during the sealing step of the cathode ray tube, and they remain in the form of metal oxides on the surface of the inner magnetic shield. Due to the heating during the sealing step, they are strongly adhered to the surface of the steel sheet. The metal oxides are not gasified in the subsequent steps, so they do not affect the service life and the like of the cathode ray tube.

In order to make it easy to distinguish the side having the coating film formed thereon particularly when it is applied to only one surface of a cold rolled steel sheet, the organic resin coating film may be colored with a coloring agent. The coloring agent is preferably selected from ones which do not generate a corrosive gas when combusted.

Next, a manufacturing method for an inner magnetic shield material according to the present invention will be described.

Cold Rolled Steel Sheet for Use as a Base Material

An annealed cold rolled steel sheet (which may be steel strip) having good magnetic properties is provided as a base material. The cold rolled steel sheet is manufactured by passing a hot rolled coil through a continuous cold rolling mill to reduce the sheet thickness to approximately a target value. By using a roll having a dull-finished surface for cold rolling, the steel sheet can be provided with a dull surface to adjust its surface roughness to 0.2-3 μm Ra at the time of cold rolling.

Cold rolling is carried out using a synthetic oil referred to as rolling oil based on palm oil or beef tallow or whale oil, and hence the rolling oil remains on the surface of the steel sheet after cold rolling. In order to remove the rolling oil, cleaning is carried out with a cleaning fluid such as a sodium hydroxide solution.

After cold rolling, annealing is carried out for recrystallization and growth of the rolled grains, which are in a fiber-like shape due to elongation during the cold rolling. As a result, the magnetic properties of the cold rolled steel sheet are improved. The annealing method may be either box annealing or continuous annealing. In general, the annealing is carried out in a non-oxidizing atmosphere such as an N₂ or N₂+H₂ atmosphere so that the surface of the steel sheet-is not oxidized, and the annealing temperature is normally 500-900° C.

After annealing, temper rolling may be carried out, if necessary, in order to flatten the steel sheet and alleviate stretcher strain and/or to adjust the surface roughness. However, temper rolling adversely affects the magnetic properties of the steel sheet. Therefore, it is preferably carried out as lightly as possible or else not carried out.

Resin Coating Film

In accordance with the present invention, an organic resin coating film having a thickness of 0.3-5 μm is formed on at least one surface of an annealed cold rolled steel sheet having a surface roughness of 0.2-3 μm Ra. The organic resin coating film is preferably formed by application of a resin coating composition followed by baking in a conventional manner. However, depending upon the resin, another drying method such as photo-setting or drying at room temperature may be employed. The resin coating composition may be solvent based or water based, but it is preferable to use a water-based coating composition from an environmental standpoint. Prior to coating, the cold rolled steel sheet is suitably washed to clean its surface.

From the standpoint of production efficiency and controlling the film thickness, the resin coating composition is frequently applied by roll coating, but other coating methods such as curtain flow coating, spray coating, and immersion coating can be used. Baking is carried out at a temperature necessary to harden the coating film which depends on the particular resin.

From the standpoint of operating efficiency, the above steps are preferably carried out continuously on a coiled cold rolled steed sheet (steel strip).

### EXAMPLES

A cold rolled steel strip having a thickness of 0.15 mm was manufactured by hot rolling and cold rolling of a low carbon, aluminum killed steel having the composition shown in Table 1 (remainder: Fe and unavoidable impurities).

TABLE 1

| Element | C | Si | Mn | P | S |
|---|---|---|---|---|---|
| mass % | 0.002 | 0.01 | 0.25 | 0.009 | 0.003 |

This cold rolled steel strip was annealed by heat treatment at 800° C. for 5 seconds in an N₂ atmosphere in continuous annealing equipment, after which it was subjected to temper rolling. In this example, the roll used in temper rolling and the rolling conditions were varied, and cold rolled steel strips adjusted to have different surface roughnesses were obtained.

After the cold rolled steel strip having its surface roughness adjusted was subjected to degreasing and then washing with water, a resin coating film was formed on both surfaces by application of a resin coating composition with a roll coater followed by baking to prepare an inner magnetic shield material. The resins which were used were based on a urethane resin, an acrylic resin, and a mixture thereof, and they were prepared from commercially available water-based coating compositions. In some test runs, a silica sol was added as a metal oxide to the resin coating composition. After application of the resin composition by roll coating, the wet coating was baked at a temperature of approximately 120° C. to obtain an inner magnetic shield material. After baking, the steel strip was air cooled and then coiled.

Table 2 shows the surface roughness (Ra) of the cold rolled steel sheet and the thickness of the resin coating film.

The corrosion resistance, the combustibility of the film, and the press workability of the inner magnetic shield material which was obtained were evaluated as follows. As conventional examples, the conventional materials described above, namely, a material on which a Ni—Fe diffusion layer was formed by annealing after Ni plating (an Ni plated material), and a material on which a blackened film primarily comprising FeO was formed by three heat treatment steps (an FeO blackened film material) were tested in the same manner. The test results for the conventional examples are also shown in Table 2.

(Corrosion Resistance)

Test pieces obtained by cutting the inner magnetic shield material to 50 mm×100 mm were coated on their surface with a usual rust preventing oil for steel sheets (mineral oil based) and were then subjected to degreasing and washing under standard conditions, and the corrosion resistance was then evaluated in an air exposure test. The air exposure test was carried out in an environment in which the test pieces were not wetted by rain or the like. During 30 days of observation, the case in which no rust developed at all was indicated by the mark ⊚, the case in which some spot rust developed was indicated by the mark Δ, and the case in which there was considerable occurrence of rust was indicated by the mark X.

The period of observation was made 30 days because in the production of an actual inner magnetic shield, unless there is some accident, a longer storage period is not necessary, and the environment of the air exposure test was one having a higher tendency towards corrosion than the environment of an actual site of use, so it was determined that 30 days of observation were appropriate.

(Combustibility of the Film)

After the surface of the same test piece as described above was coated with a usual rust preventing oil for steel sheets (mineral oil based), degreasing and washing were carried out for as short a degreasing and washing time as possible in a situation in which a cold rolled steel sheet could be degreased. Then, it was heated in air at 450° C. for 15 minutes. The heating conditions were set so as to simulate the sealing step of a cathode ray tube. It was determined by EPMA analysis whether resin remained on the surface of the test piece after heating. In addition, the amount of gas generated in the heat treatment was measured over time to ascertain whether the generation of gas ceased during the heat treatment of the sealing step. Furthermore, a gas sample was analyzed by the TG-MS method and the Pyro-GC-MS method to check whether any corrosive gas containing S, Cl, F, or the like was generated.

For the results, the case in which a resin did not remain after heat treatment under the above-described conditions, the generation of gas ceased during heat treatment, and a corrosive gas was not generated was indicated by the mark ⊚, and the case in which it was ascertained that some resin remained, or in which the generation of gas did not cease during heat treatment, or in which a corrosive gas was generated was indicated by the mark X.

For the conventional materials, the film does not combust, so the properties other than whether a resin coating film remained, i.e., whether the generation of gas ceased during heat treatment or whether a corrosive gas was generated were evaluated in the same manner as described above.

(Press Workability)

Each coiled inner magnetic shield material was subjected to punching and subsequent press working with a bending die or a drawing die using a press working apparatus equipped with an uncoiler while it was fed with a measuring roll, in order to ascertain its workability.

For examples of the present invention and comparative examples, press workability was evaluated in the following manner with respect to slippage of an inner magnetic shield material during feeding with a measuring roll and transportability of a blank after punching (whether a plurality of blanks were transported at the same time by sticking of the materials to each other):

⊚: material of a prescribed length could be fed without slipping by a measuring roll, the transportability of blanks after punching was good, and there were no problems at all in a series of press working steps;

Δ: there was no slip when the material was fed by a measuring roll, but when a blank was transferred after punching, there was a tendency for troubles to occur such as for a plurality of blanks to be transported at the same time;

X: slippage occurred when the material was fed by a measuring roll, and a series of press working steps could not be performed in a stable manner.

With the conventional material, the problems of press working were not slippage at the time of transport or blanks sticking to each other, but were a decrease in the service life of dies due to wear of the dies caused by the surface film being too hard. Therefore, the extent of wear of the dies during continuous punching was used to evaluate press workability by comparing the height of burrs formed by punching, which was determined on a cut cross section of a blank, with that for a cold rolled steel sheet. The height of burrs on a cut cross section of a blank increases as working (punching) is repeated with a die. Compared to a typical cold rolled steel sheet, the change in the height of burrs was indicated by the mark ⊚ when there was no substantial difference from a cold rolled steel sheet, and by the mark X when the height of burrs clearly became higher more rapidly than for a cold rolled steel sheet.

TABLE 2

| | | Surface | Organic resin coating | | | | |
|---|---|---|---|---|---|---|---|
| | Test | rougness | film (thickness: μm) | | Corrosion | Film | Press |
| Category | No. | (μm) | Resin type | Thickness | resistance | combustibility | workability |
| This | 1 | 0.21 | urethane | 2.2 | ⊚ | ⊚ | ⊚ |
| invention | 2 | 0.42 | urethane | 2.0 | ⊚ | ⊚ | ⊚ |
| | 3 | 0.80 | urethane | 2.3 | ⊚ | ⊚ | ⊚ |
| | 4 | 0.97 | urethane | 2.3 | ⊚ | ⊚ | ⊚ |
| | 5 | 1.20 | urethane | 2.1 | ⊚ | ⊚ | ⊚ |
| | 6 | 3.00 | urethane | 2.0 | ⊚ | ⊚ | ⊚ |
| | 7 | 0.23 | urethane | 0.3 | ⊚ | ⊚ | ⊚ |
| | 8 | 0.95 | urethane | 1.5 | ⊚ | ⊚ | ⊚ |
| | 9 | 1.21 | urethane | 3.2 | ⊚ | ⊚ | ⊚ |
| | 10 | 1.15 | urethane | 5.0 | ⊚ | ⊚ | ⊚ |
| | 11 | 0.92 | acrylic | 0.8 | ⊚ | ⊚ | ⊚ |
| | 12 | 1.77 | acrylic | 3.2 | ⊚ | ⊚ | ⊚ |
| | 13 | | urethane + | 0.9 | ⊚ | ⊚ | ⊚ |
| | | 0.85 | acrylic | | | | |
| | 14 | 1.52 | urethane + | 2.8 | ⊚ | ⊚ | ⊚ |
| | | | acrylic | | | | |
| | 15 | 1.10 | urethane + | 2.2 | ⊚ | ⊚ | ⊚ |
| | | | SiO₂ (5%) | | | | |
| | 16 | 0.97 | urethane + | 1.9 | ⊚ | ⊚ | ⊚ |
| | | | SiO₂ (50%) | | | | |
| Comparative | 17 | 0.12* | urethane | 2.0 | ⊚ | ⊚ | x |
| Examples | 18 | 0.17* | urethane | 2.2 | ⊚ | ⊚ | Δ˜x |
| | 19 | 3.32* | urethane | 2.1 | x | ⊚ | ⊚ |
| | 20 | 4.25* | urethane | 2.3 | x | ⊚ | ⊚ |
| | 21 | 0.85 | urethane | 0.1* | Δ | ⊚ | ⊚ |
| | 22 | 0.92 | urethane | 5.7* | ⊚ | x | ⊚ |
| | 23 | 0.87 | urethane | 6.8* | ⊚ | x | ⊚ |
| Conventional | 24 | 0.82 | Ni plating + | — | Δ | x | Δ |
| material | | | annealing | | | | |
| | 25 | 0.57 | FeO-based | — | x | x | x |
| | | | blackened | | | | |
| | | | film | | | | |

*Conditions outside the range of the present invention.

As can be seen from Table 2, an inner magnetic shield material according to the present invention having a resin coating film with a thickness of 0.3-5 μm formed on a cold rolled steel sheet with a surface roughness of 0.2-3 μm had good corrosion resistance, film combustibility, and press workability, regardless of the type of resin. In addition, rust preventing oil could be sufficiently removed by washing even when subjected to the harsh degreasing and washing used in the film combustibility test.

On the other hand, as shown for the comparative examples, when the surface roughness exceeded 3 μm, significant rusting occurred during the air exposure test, and the corrosion resistance was inferior. Similarly, when the film thickness was less than 0.3 μm, spot rust occurred, and corrosion resistance decreased. When the film thickness exceeded 5 μm, the resin coating film could not completely undergo combustion and decomposition during heating in the sealing step. This remaining resin will become a hindrance in the subsequent degasification step. When the surface roughness of the cold rolled steel sheet was less than 0.2 μm, not only did slippage occur during feeding with a measuring roll, thereby making it impossible to feed the material by an accurate length, but at the time of transport of the blanks, the transport problem occurred that a plurality of blanks sticked to each other.

With the conventional material, both for the Ni plated material and the blackened film material, the film combustibility in particular was bad. This indicates that when degreasing and washing are carried out after press working, if the degreasing and washing conditions are harsh, the lubricating oil cannot be completely removed, and a large amount of gas is generated during the sealing step. Furthermore, the corrosion resistance and press workability were inadequate, with this tendency being particularly strong for the blackened film material. The decrease in press workability was because the service life of punching dies and the like decreased due to the surface layer being hard.

The best mode and embodiments of the present invention have been described above, but these are examples, and all manner of variations are possible are within the scope of the present invention.

1. An inner magnetic shield material for use in manufacturing an inner magnetic shield to be installed inside a cathode ray tube for a color television, characterized in that it comprises a cold rolled steel sheet having a coating film of an organic resin consisting essentially of C and H, or of C, H, and O, or of C, H, O, and N with a thickness of 0.3-5 μm on at least one surface of the steel sheet having a surface roughness of 0.2-3 μm Ra.

2. An inner magnetic shield material as claimed in claim 1, wherein the cold rolled steel sheet is selected from aluminum killed steel sheet, silicon killed steel sheet, aluminum trace steel sheet, and silicon trace steel sheet.

3. An inner magnetic shield material as claimed in claim 1 or claim 2, wherein the organic resin coating film is a film of a resin selected from urethane resins, acrylic resins, and polyester resins.

4. An inner magnetic shield material as claimed in claim 3 wherein the organic resin coating film contains a metal oxide.

5. A method of manufacturing a material for an inner magnetic shield to be installed inside a cathode ray tube for a color television, characterized by forming a coating film of an organic resin consisting essentially of C and H, or of C, H, and O, or of C, H, O, and N and having a thickness of 0.3-5 μm on at least one surface of an annealed cold rolled steel sheet adjusted to have a surface roughness of 0.2-3 μm Ra by application of a resin coating composition followed by baking.

6. A method as claimed in claim 5, wherein the cold rolled steel sheet is selected from aluminum killed steel sheet, silicon killed steel sheet, aluminum trace steel sheet, and silicon trace steel sheet.

7. A method as claimed in claim 5 or claim 6, wherein the organic resin coating film is a film of a resin selected from urethane resins, acrylic resins, and polyester resins.

8. A method as claimed in claim 7 wherein the organic resin coating film contains a metal oxide.
